(19) United States
(12) Patent Application Publication
(10) Pub. No.: US 2012/0097440 A1
(43) Pub. Date: Apr. 26, 2012

(54) METHOD FOR ELECTRONIC COMPONENT LAYOUT OF CIRCUIT BOARD AND PRINTED CIRCUIT BOARD STRUCTURE

(75) Inventor: Chung Yang Wu, Taipei (TW)

(73) Assignee: INVENTEC CORPORATION, Taipei (TW)

(21) Appl. No.: 13/019,371

(22) Filed: Feb. 2, 2011

(30) Foreign Application Priority Data
Oct. 22, 2010 (TW) 099136212

(51) Int. Cl. H05K 1/18; H05K 3/34

(52) U.S. Cl. 174/260; 29/840

(57) ABSTRACT

A method for electronic component layout of a printed circuit board includes the following steps. First, a first solder joint is formed on a first surface of the printed circuit board. Then, an electronic component is clipped on a side edge of the printed circuit board in an installation direction. At this time, a first pin of the electronic component is placed on the first solder joint, and presses against a limiting portion of the first solder joint, and a second pin of the electronic component is placed on a second surface of the printed circuit board. Finally, a second solder joint is formed on the second surface, so that the second pin is fixed on the second solder joint and the first pin is fixed on the first solder joint.

### CROSS-REFERENCE TO RELATED APPLICATIONS

This non-provisional application claims priority under 35 U.S.C. §119(a) on Patent Application No(s). 099136212 filed in Taiwan, R.O.C. on Oct. 22, 2010, the entire contents of which are hereby incorporated by reference.

### BACKGROUND OF THE INVENTION

1. Field of Invention

The present invention relates to a method for electronic component layout, and more particularly to a method for electronic component layout of a printed circuit board and a printed circuit board structure.

2. Related Art

Nowadays, with the continuous innovation and advancement of computer and electronic technology, various electronic products are widely used in the society. Moreover, with the fast development of technology, both computers and electronic products are developed towards the trend of strong operational capability, high speed, and small volume. Therefore, electrical connectors for connecting to various peripherals to transmit electrical signals on a main board in a computer also increase greatly. However, since the current design of a computer device is developed towards the trend of miniaturization, and the available space in the computer device is relatively small, an electrical connector electrically installed on a main board is required to be miniaturized accordingly and the original arrangement needs to be changed.

In the prior art, an electrical connector is disposed on a printed circuit board mainly in two manners: a vertical manner and a side-clipping manner. The electrical connector installed in the side-clipping manner is usually applicable to a special double-sided printed circuit board. The conventional side-clipped electrical connector includes many pairs of up-down symmetrical pins, so as to improve the stability of the electrical connector when being clamped. Mutually symmetrical pads are respectively disposed on two opposite sides of the printed circuit board. The two rows of pins of the electrical connector are fixed on the pads through a solder, thus forming electrical conduction.

In order to avoid too complex process steps of forming pads for a printed circuit board, the conventional method is as follows. First, a solder is printed on a pad on one side of the printed circuit board (usually the back side of the printed circuit board), and then a first side reflow step is performed on the printed circuit board, so that the solder is formed into a solid and protruding solder joint. The side-clipped electrical connector is clipped at the side of the printed circuit board, and one row of pins of the electrical connector is located on the solder joint and the other row of pins is located on the pad of the printed circuit board. Then, a solder is printed on a pad on the other side of the printed circuit board (usually the front side of the printed circuit board), and a second side reflow step is performed, so that the solder on the other side of the printed circuit board is formed into a solder joint, thus enabling the electrical connector to be fixed on the printed circuit board.

However, the above conventional printed circuit board structure and process steps have the following problem. When the second side reflow process is performed on the printed circuit board, the pins of the electrical connector located on the solder joint on the first side may expand with heat and contract with cold due to the high temperature in the reflow oven. At this time, the pins of the electrical connector slide and deviate from the top end of the solder joint, so that the electrical connector departs from the preset installation position without closely contacting the printed circuit board.

Since a gap exists between the electrical connector and the printed circuit board, the gap defect causes interference between the relative positions of the electrical connector and an electronic component or a case adjacent to the printed circuit board in the subsequent assembly process of the printed circuit board, thus resulting in the problem of poor assembly of the printed circuit board.

### SUMMARY OF THE INVENTION

Accordingly, the present invention relates to a method for electronic component layout of a printed circuit board and a printed circuit board structure, for reducing the problem that due to the limitation of the conventional printed circuit board structure and process steps, pins of an electrical connector slide and deviate from a solder joint on a printed circuit board in the reflow process, so that the electrical connector departs from a preset position without closely contacting the printed circuit board.

The present invention provides a method for electronic component layout of a printed circuit board, which comprises the following steps. First, a printed circuit board having a first surface and a second surface opposite to each other is provided, and a first solder joint is formed on the first surface of the printed circuit board. Then, an electronic component is clipped on a side edge of the printed circuit board in an installation direction. A first pin of the electronic component is placed on the first solder joint, and presses against a limiting portion of the first solder joint, and a second pin of the electronic component is placed on a second surface of the printed circuit board. Finally, a second solder joint is formed on the second surface, and the second pin is fixed on the second solder joint and the first pin is fixed on the first solder joint.

The efficacy of the present invention lies in that, through the configuration that the pin of the electronic component presses against the limiting portion of the formed solder joint, the limiting portion can resist the slide and deviation of the pin due to expansion with hot or contraction with cold. Therefore, after the reflow process is performed, the electronic component is still closely attached to the side edge of the printed circuit board, and maintains good electrical conduction with the printed circuit board, thus effectively avoiding the problem of poor assembly of the printed circuit board in the subsequent assembly process.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 is a flow chart of steps of an embodiment of the present invention; and

FIGS. 2A to 2D are schematic views of steps of an embodiment of the present invention.

### DETAILED DESCRIPTION OF THE INVENTION

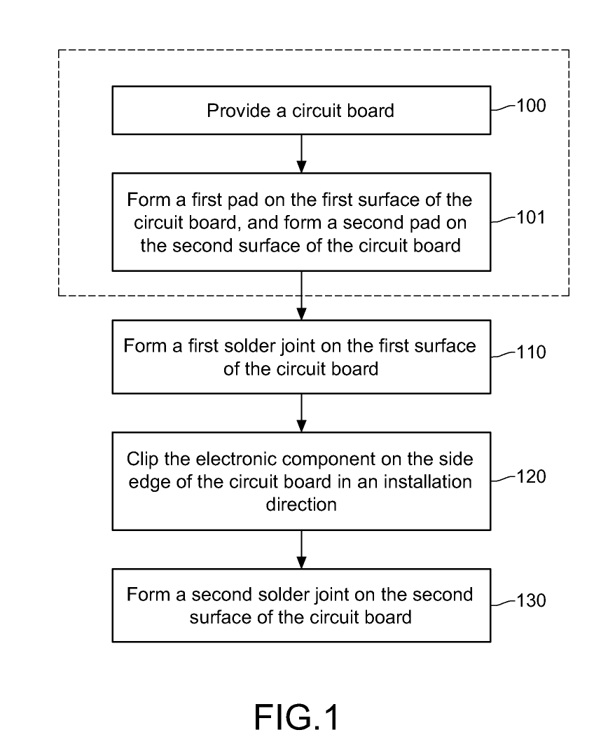

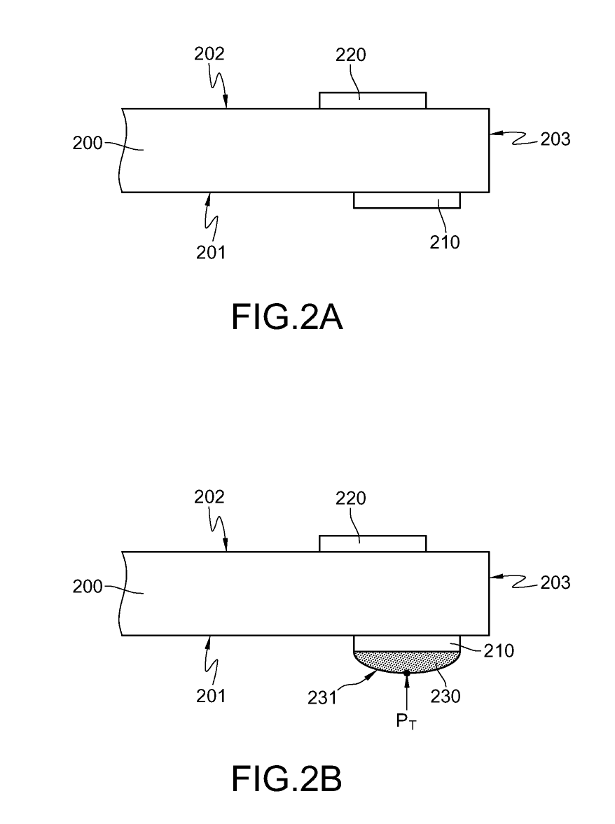

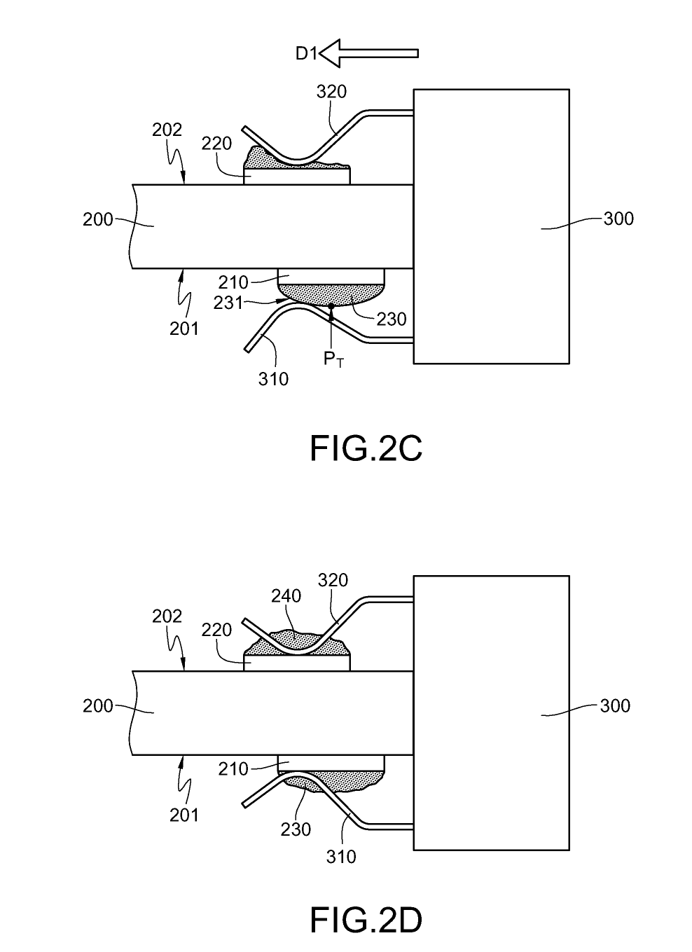

FIG. 1 is a flow chart of steps of an embodiment of the present invention, and FIGS. 2A to 2D are schematic views of detailed steps of an embodiment of the present invention.

Referring to FIG. 1 in combination with FIG. 2A, a method for electronic component layout of a printed circuit board according to the present invention comprises the following steps. First, a printed circuit board 200 is provided (Step 100), in which the printed circuit board 200 has a first surface 201 and a second surface 202 opposite to each other (the first surface 201 is the bottom surface of the printed circuit board 200, and the second surface 202 is the top surface of the printed circuit board 200), and the printed circuit board 200 also has a side edge 203.

The printed circuit board 200 in this embodiment is a surface mount circuit substrate to facilitate the subsequent surface mount technology (SMT) process. That is to say, a first pad 210 is formed on the first surface 201 of the printed circuit board 200, and a second pad 220 is formed on the second surface 202 of the printed circuit board 200 (Step 101).

It should be noted that, the relative positions of the first pad 210 and the second pad 220 in this embodiment overlap partially, thus forming an asymmetrical structural design, and the first pad 210 is disposed closer to the side edge 203 of the printed circuit board 200 than the second pad 220.

In addition, in this embodiment, the first pad 210 and the second pad 220 may be directly formed respectively on the first surface 201 and the second surface 202 of the printed circuit board 200 by screen printing. Alternatively, a patterning process is performed on the first pad 210 and the second pad 220 which are mutually symmetrical through a solder mask, so that the first pad 210 and the second pad 220 form an asymmetrical structural pattern.

Then, a first solder joint 230 is formed on the first surface 201 of the printed circuit board 200 (Step 110). Specifically, the step of forming the first solder joint 230 is to first coat a solder on the first pad 210 on the first surface 201 of the printed circuit board 200, and then perform a first reflow process on the printed circuit board 200, so that the solder is formed into the first solder joint 230. The first solder joint 230 has a top end P_{T} located at the highest position of the protrusion of the first solder joint 230, and the first solder joint 230 further has a limiting portion 231 located on one side of the first solder joint 230 that is away from the side edge 203.

Then, an electronic component 300 is provided. A side edge 203 of the electronic component 300 has at least one first pin 310 and at least one second pin 320 spaced apart from each other. The first pin 310 is located on the lower part of the electronic component 300, and the second pin 320 is located on the upper part of the electronic component 300 (see the elements shown in FIG. 2C). The first pin 310 and the second pin 320 are designed in the form of gull pins. Then, the electronic component 300 is clipped on the side edge 203 of the printed circuit board 200 in an installation direction Dl through a jig (not shown), and the electronic component 300 is closely attached to the side edge 203 of the printed circuit board 200 (Step 120).

At this time, the first pin 310 of the electronic component 300 is placed on the first solder joint 230 on the first surface 201 of the printed circuit board 200, and the second pin 320 of the electronic component 300 is placed on the second pad 220 on the second surface 202 of the printed circuit board 200. The first pin 310 of the electronic component 300 presses against the limiting portion 231 across the top end P_{T} of the first solder joint 230, so that the first pin 310 and the first solder joint 230 press against each other with a relatively large contact area.

The first electronic component 400 according to the present invention is a surface mount device (SMD), for example, but not limited to, an electrical connector.

It should be noted that, through the asymmetrical structural design of the first pad 210 and the second pad 220 in this embodiment, the first pin 310 of the electronic component 300 can press against the limiting portion 231 across the top end P_{T} of the first solder joint 230. However, persons skilled in the art may also design the first pin 310 and the second pin 320 of the electronic component 300 into an asymmetrical structure, so as to achieve the same configuration, which is not limited to this embodiment.

Referring to FIGS. 1, 2C, and 2D, finally, a second solder joint 240 is formed on the second surface 202 of the printed circuit board 200 (Step 130). Specifically, the step of forming the second solder joint 240 is to first coat a solder on the second pad 220 on the second surface 202 of the printed circuit board 200, so as to wrap the second pin 320 of the electronic component 300, and then perform a second reflow process on the printed circuit board 200, so that the solder is formed into the second solder joint 240 and the second pin 320 of the electronic component 300 is fixed on the second solder joint 240. At the same time when the second reflow process is preformed, the first solder joint 230 is also heated and melted again, and wraps the first pin 310 of the electronic component 300, so that the first pin 310 of the electronic component 300 is fixed on the first solder joint 230 at the same time, thus forming good electrical conduction between the electronic component 300 and the printed circuit board 200. Since the first pin 310 is stopped by the limiting portion 231 of the first solder joint 230 and remains at the preset position, thus avoiding the phenomenon that the first pin 310 deviates due to expansion with hot or contraction with cold, after the second reflow process is performed, the electronic component 300 is still closely attached to the side edge 203 of the printed circuit board 200 without departing there-from.

Through the method for electronic component layout of the printed circuit board and the printed circuit board structure according to the present invention, the pin of the electronic component crosses the top end of the solder joint of the printed circuit board in the installation direction and presses against the limiting portion of the solder joint. When the pin of the electronic component slides due to expansion with hot and contraction with cold in the reflow process, the limiting portion provides the function of limiting the deviation of the pin. In this way, after the printed circuit board accomplishes the second reflow process, the electronic component is still closely attached to the side edge of the printed circuit board, and maintains good electrical conduction with the printed circuit board, thus effectively avoiding the problem of poor assembly of the printed circuit board in the subsequent assembly process.

What is claimed is:

1. A method for electronic component layout of a printed circuit board, comprising:
providing a printed circuit board, wherein the printed circuit board has a first surface and a second surface opposite to each other;
forming a first solder joint on the first surface;
clipping an electronic component on a side edge of the printed circuit board in an installation direction, wherein at least one first pin of the electronic component is placed on the first solder joint, and the first pin presses against a limiting portion of the first solder joint, and at least one second pin of the electronic component is placed on the second surface; and
forming a second solder joint on the second surface, wherein the second pin is fixed on the second solder joint, and the first pin is fixed on the first solder joint.

2. The method for electronic component layout of the printed circuit board according to claim 1, wherein the step of providing the printed circuit board further comprises:
forming a first pad on the first surface of the printed circuit board, and forming a second pad on the second surface of the printed circuit board, wherein the first solder joint is formed on the first pad, and the second solder joint is formed on the second pad.

3. The method for electronic component layout of the printed circuit board according to claim 1, wherein the step of forming the first solder joint on the first surface further comprises:
coating a solder on the first surface of the printed circuit board; and
performing a first reflow process, so that the solder is formed into the first solder joint.

4. The method for electronic component layout of the printed circuit board according to claim 1, wherein the step of forming the second solder joint on the second surface further comprises:
disposing a solder on the second surface of the printed circuit board; and
performing a second reflow process, so that the solder is formed into the second solder joint and wraps the second pin, the second pin is fixed on the second solder joint, and the first solder joint wraps the first pin, and the first pin is fixed on the first solder joint.

5. A printed circuit board structure, applicable in a circuit layout process of an electronic component, wherein the electronic component has at least one first pin and at least one second pin spaced apart from each other, the printed circuit board structure comprising:
a printed circuit board, having a first surface and a second surface opposite to each other, and having a side edge, wherein the electronic component is clipped on the side edge in an installation direction;
a first solder joint, disposed on the first surface of the printed circuit board, wherein the first solder joint has a limiting portion, the first pin of the electronic component presses against the limiting portion, and the first pin is fixed on the first solder joint; and
a second solder joint, disposed on the second surface of the printed circuit board, wherein the second pin of the electronic component is fixed on the second solder joint, so that the electronic component and the printed circuit board are electrically conducted.

6. The printed circuit board structure according to claim 5, further comprising a first pad and a second pad, wherein the first pad is disposed on the first surface of the printed circuit board, the second pad is disposed on the second surface of the printed circuit board, the first solder joint is located on the first pad, and the second solder joint is located on the second pad.
